(19) United States
(12) Patent Application Publication
(10) Pub. No.: US 2008/0185178 A1
(43) Pub. Date: Aug. 7, 2008

(54) Circuit board and method for manufacturing the same, semiconductor package, component built-in module and board for electronic equipment

(75) Inventors: Rikiya Okimoto, Katano-shi (JP); Yoji Ueda, Osaka-shi (JP); Satoru Tomekawa, Kishiwada-shi (JP); Tousaku Nishiyama, Nara-shi (JP); Shozo Ochi, Takatsuki-shi (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi (JP)

(21) Appl. No.: 12/011,725

(22) Filed: Jan. 29, 2008

Related U.S. Application Data
(63) Continuation of application No. 11/003,680, filed on Dec. 3, 2004, now abandoned.

(30) Foreign Application Priority Data
Dec. 4, 2003 (JP) 2003-406468
Mar. 25, 2004 (JP) 2004-089581

(51) Int. Cl. H05K 1/11

(52) U.S. Cl. 174/264

(57) ABSTRACT

A circuit board of the present invention, includes: an electrical insulating layer including at least one layer of electrical insulating base; and a conductive portion formed in a via hole provided in the electrical insulating base. A land for mounting only is disposed on at least one surface of the electrical insulating base that is arranged at an outermost layer. According to a method for manufacturing a circuit board of the present invention, includes the steps of: forming a via hole in an electrical insulating base; filling the via hole with a conductive paste; laminating a metal foil or a releasing sheet on the electrical insulating base, and placing a jig for pressing above and below the lamination, followed by hot-pressing so as to apply heat and pressure thereto, so as to form a conductive portion made of the conductive paste in the via hole; and forming a land for mounting only on at least one surface of the electrical insulating base that is arranged at an outermost layer. Thereby, a circuit board can be provided, having a land for mounting formed with a narrow pitch.

This application is a continuation of application U.S. Ser. No. 11/003,680, filed Dec. 3, 2004, which application is incorporated herein by reference.

### FIELD OF THE INVENTION

The present invention relates to a circuit board and a method for manufacturing the same, by which a land for mounting (hereinafter also referred to as “mounting land”) can be formed with a narrow pitch, and relates to a semiconductor package, a component built-in module and a board for electronic equipment that are manufactured using this circuit board.

### BACKGROUND OF THE INVENTION

In recent years, along with the miniaturization of electronic equipment having advanced performance, a circuit board that allows components such as a large scale integrated circuit (LSI) to be mounted densely has been demanded strongly. In such a circuit board, it is important to form lands with a narrow pitch and to make the electrical connection between circuit patterns in a plurality of layers with high reliability.

Conventionally, the interlayer connection of a circuit board has been implemented by coating an inner wall of a through hole provided in the board with plating. Meanwhile, in response to the above-stated demands, a method for implementing the interlayer connection by filling a via hole in a circuit board with a conductive paste has been proposed for example in JP H06 (1994)-268345 A (hereinafter, this method will be referred to as an “inner via hole connection method”). This method enables the via hole to be provided directly below a land, thus realizing the miniaturization of a size of the board and high-density mounting.

FIGS. 12A to I are cross-sectional views for explaining one example of the inner via hole connection method. According to this method, firstly, a protective film 1102 is laminated on each of the surface and the rear face of a compressible electrical insulating base 1101 (FIG. 12A), and via holes 1103 are formed at desired positions by means of laser processing or the like (FIG. 12B). Next, a conductive paste 1104 is filled in the via holes 1103 by means of printing or the like (FIG. 12C), followed by peeling-off of the protective films 1102. Thus, the conductive paste 1104 remains like a protrusion that has a dimension corresponding to the thickness of the protective film 1102 (FIG. 12D). Moreover, a metal foil 1105 is disposed on each of the surface and the rear face of the electrical insulating base 1101 (FIG. 12D), followed by hot pressing, whereby the metal foils 1105 are bonded to the electrical insulating base 1101 (FIG. 12E). This hot pressing allows the electrical insulating base 1101 and the conductive paste 1104 to be compressed in the thickness direction of the electrical insulating base 1101. Thereby, metal fillers included in the conductive paste 1104 contact with each other densely, so as to form conductive portions 1104a and to establish the electrical connection between the metal foils 1105 and the conductive portions 1104a. Next, the metal foils 1105 are patterned to have a desired circuit pattern, thus obtaining a double-sided circuit board 1108 (FIG. 12F). The above-stated circuit pattern includes wirings for signals 1106, lands 1107 and the like.

Then, on each of the surface and the rear face of the double-sided circuit board 1108, a metal foil 1105 and an electrical insulating base 1101 that is manufactured by the same process as in FIGS. 12A to D, in which the conductive paste 1104 has been filled, are disposed (FIG. 12G), followed by hot pressing. Thereby, the metal foils 1105, the electrical insulating bases 1101 and the double-sided circuit board 1108 are bonded to each other (FIG. 12H). Moreover, the metal foils 1105 on the surface layers are patterned to have a desired circuit pattern, thus obtaining a circuit board 1109 (FIG. 12I).

The thus described inner via hole connection method, however, has a limit to narrow the land pitch to a predetermined threshold value (e.g., a via hole pitch) or smaller in order to ensure the reliability concerning electrical connection and electrical insulation and to ensure the registration of the via holes with the lands and in terms of the influence on the wiring for signals.

### SUMMARY OF THE INVENTION

Therefore, with the foregoing in mind, it is an object of the present invention to provide a circuit board and a method for manufacturing the same that allows a mounting land to be formed with a narrow pitch, and to provide a semiconductor package, a component built-in module and a board for electronic equipment that are manufactured using this circuit board.

A circuit board of the present invention includes: an electrical insulating layer including at least one layer of electrical insulating base; and a conductive portion formed in a via hole provided in the electrical insulating base. A land for mounting only is disposed on at least one of surfaces of the electrical insulating base that is arranged at an outermost layer. Note here that the “surfaces of the electrical insulating base that is arranged at an outermost layer” refers to: when the electrical insulating layer includes a single layer of the electrical insulating base, the surface and the rear face of such an electrical insulating base; and when the electrical insulating layer includes a plurality of layers of electrical insulating bases, the outer surfaces of the respective electrical insulating bases that are arranged at the outermost layers.

A method for manufacturing a circuit board of the present invention, includes steps of: forming a via hole in an electrical insulating base; filling the via hole with a conductive paste; laminating a metal foil or a releasing sheet on the electrical insulating base, and placing a jig for pressing above and below the lamination, followed by hot-pressing so as to apply heat and pressure thereto, so as to form a conductive portion made of the conductive paste in the via hole; and forming a land for mounting only on at least one of surfaces of the electrical insulating base that is arranged at an outermost layer.

A semiconductor package of the present invention includes: the afore-mentioned circuit board of the present invention, and a component mounted in the circuit board.

A component built-in module of the present invention includes: the afore-mentioned circuit board of the present invention; a component mounted in the circuit board; and an electrical insulating base for including the component therein.

A board for electronic equipment of the present invention includes the afore-mentioned semiconductor package of the present invention.

### BRIEF DESCRIPTION OF THE DRAWINGS

FIG. 1 shows the outermost layers of a circuit board in plan view, which is according to Embodiment 1 of the present invention, where FIG. 1A shows a component mounting side and FIG. 1B shows a secondary mounting side.

FIGS. 2A to 2C are cross-sectional views showing a method for manufacturing a circuit board according to Embodiment 1 of the present invention.

FIGS. 3A and 3B are cross-sectional views showing a method for manufacturing a circuit board according to Embodiment 2 of the present invention.

FIGS. 4A to 4C are cross-sectional views showing a method for manufacturing a circuit board according to Embodiment 3 of the present invention.

FIG. 5 is a cross-sectional view of a semiconductor package according to Embodiment 4 of the present invention.

FIG. 6A is a cross-sectional view of a semiconductor package according to Embodiment 5 of the present invention, and FIG. 6B is a cross-sectional view showing a modified example of the semiconductor package shown in FIG. 6A.

FIG. 7 is a cross-sectional view of a component built-in module according to Embodiment 6 of the present invention.

FIG. 8 is a cross-sectional view of a board for electronic equipment according to Embodiment 7 of the present invention.

FIG. 9A is a cross-sectional view of a circuit board according to Embodiment 8 of the present invention, and FIG. 9B is a plan view showing an internal layer wiring pattern and an interlayer connection land disposed inside the circuit board according to Embodiment 8.

FIG. 10 is a graph showing transmission losses of the circuit boards according to Embodiment 8 of the present invention.

FIGS. 11A to 11K are cross-sectional views showing a method for manufacturing a board for electronic equipment that is a working example of the present invention.

FIGS. 12A to 12I are cross-sectional views showing a method for manufacturing a conventional circuit board.

### DETAILED DESCRIPTION OF THE INVENTION

A circuit board of the present invention includes: an electrical insulating layer including at least one layer of electrical insulating base; and a conductive portion formed in a via hole provided in the electrical insulating base. As the electrical insulating base, a porous base having compressibility; a base having a three-layered structure including adhesive layers formed on both sides of a core base; a composite base of fiber and a resin, etc. are used favorably. For instance, a porous composite base prepared by impregnating aromatic polyamide fiber with a thermosetting epoxy resin, which is then treated to be porous and the like are used favorably. Herein, a thickness of the electrical insulating base may be 50 to 150 μm, for example, preferably 80 to 100 μm. The via hole may be formed by means of laser processing, punching or the like. As described later, it is preferable to form the conductive portion by filling the via hole with a conductive paste, followed by compression.

In the circuit board of the present invention, a land for mounting only may be disposed on at least one surface of the electrical insulating base that is arranged at an outermost layer. That is, since at least surface at the outermost layer is free from a conductive member other than lands for mounting (e.g., free from signal wirings), the land for mounting can be formed with a narrow pitch without the influence of wirings for signals and the like. Furthermore, in the circuit board of the present invention, preferably, the land for mounting only is disposed on each of both surfaces of the electrical insulating base that is arranged at the outermost layer. With this configuration, a pitch of the land for mounting can be narrowed more easily.

Furthermore, a surface of the land for mounting that is provided in the circuit board of the present invention may be polished. During the upstream steps prior to the mounting of a component, the surface of the land for mounting is coated with an oxide film that is formed by a chemical treatment and a heat treatment and with residual salts due to various treatment agents, and they can be removed by the polishing of the surface. Thereby, the bonding strength between the component and the circuit board can be enhanced when the component is mounted. Furthermore, preferably, a surface of the land for mounting that is provided in the circuit board of the present invention is plated. Thereby, the bonding strength between the component and the circuit board further can be enhanced when the component is mounted.

In the case where the electrical insulating layer of the present invention includes two layers or more of the electrical insulating bases, the circuit board of the present invention further may include a wiring pattern disposed between the plurality of electrical insulating bases and an interlayer connection land that is electrically connected with the conductive portion, and when viewing the interlayer connection land from a direction of an axis of the conductive portion, the interlayer connection land may be disposed inside an outer edge of the conductive portion. With this configuration, a pitch of the interlayer connection land can be narrowed, so that densification of the wiring can be realized easily. Furthermore, in the afore-mentioned configuration, the wiring pattern may be formed with a wiring thinner than a diameter of the conductive portion, and a part of the wiring pattern that is connected with the interlayer connection land may be disposed so as to contact with the conductive portion. With this configuration, densification of the wiring can be realized more easily. Furthermore, preferably, in the afore-mentioned configuration, when viewing the wiring pattern from the direction of the axis of the conductive portion, a portion of the wiring pattern that is disposed on the conductive portion has an area that is 10% or more of a cross-sectional area of the conductive portion in a radial direction. With this configuration, densification of the wiring can be realized still more easily. Furthermore, preferably, in the afore-mentioned configuration, when viewing the wiring pattern and the interlayer connection land from the direction of the axis of the conductive portion, a total area of a portion of the wiring pattern that is disposed on the conductive portion and an area of the interlayer connection land is 10% or more and less than 100% of a cross-sectional area of the conductive portion in a radial direction. Also with this configuration, densification of the wiring can be realized still more easily.

If the total area of a portion of the wiring pattern that is disposed on the conductive portion and an area of the interlayer connection land is less than 10% of a cross-sectional area in a radial direction of the conductive portion, the electrical connection between the conductive portion and the wiring pattern or the interlayer connection land might become instable. Whereas, if the total area becomes closer to 100%, the registration of the conductive portion with the interlayer connection land may be degraded. Therefore, the preferable total area is 30 to 50% of the cross-sectional area.

A method for manufacturing a circuit board of the present invention, includes steps of forming a via hole in an electrical insulating base; filling the via hole with a conductive paste; laminating a metal foil or a releasing sheet on the electrical insulating base, and placing a jig for pressing above and below the lamination, followed by hot-pressing so as to apply heat and pressure thereto, so as to form a conductive portion made of the conductive paste in the via hole; and forming a land for mounting only on at least one surface of the electrical insulating base that is arranged at an outermost layer. The conductive paste filled in the via hole preferably includes at least one metal selected from the group consisting of silver, copper and nickel. Since the use of the afore-mentioned metals increases the conductivity of the conductive paste, the interlayer connection with high reliability can be realized. Alternatively, an alloy that is composed of at least one metal selected from the group consisting of silver, copper and nickel may be used for the conductive paste filled in the via hole. Furthermore, the conductive paste used for the present invention may include copper powder coated with silver. With this configuration, the conductivity of the conductive paste is increased, and therefore the reliability of the interlayer connection can be enhanced.

As a method for forming the land for mounting, when applying heat and pressure by the hot-pressing, a metal foil may be laminated on at least one surface of the electrical insulating base that is arranged at an outermost layer, and the land for mounting may be formed by etching the metal foil all over the surface so as to expose the conductive portion. Thereby, the land for mounting can be formed to have the same pitch as the pitch of the via hole, and the circuit board of the present invention can be manufactured easily to have a land for mounting with a narrow pitch.

As another method for forming the land for mounting, when applying heat and pressure by the hot-pressing, a metal foil may be laminated on at least one surface of the electrical insulating base that is arranged at an outermost layer, and the land for mounting may be formed by pattern-etching of the metal foil so as to have a circular shape with a diameter equal to or smaller than a diameter of the via hole. With this method also, the circuit board of the present invention can be manufactured easily to have a land for mounting with a narrow pitch.

As still another method for forming the land for mounting, when applying heat and pressure by the hot-pressing, a releasing sheet may be laminated on at least one surface of the electrical insulating base that is arranged at an outermost layer, and the land for mounting may be formed by peeling off the releasing sheet so as to expose the conductive portion. With this method also, the circuit board of the present invention can be manufactured easily to have a land for mounting with a narrow pitch. Herein, the releasing sheet is not limited especially, and a sheet member made of a fluoro resin and having a thickness of about 100 μm and the like favorably are used. Since the releasing sheet can be peeled off easily, the step for forming the land for mounting can be simplified.

A semiconductor package of the present invention includes: the afore-mentioned circuit board of the present invention, and a component mounted with the circuit board, such as a LSI. With this configuration, a semiconductor package with densely mounted components can be provided. In order to ensure the reliability of the electrical connection, preferably, a component is mounted in the semiconductor package of the present invention by at least one method selected from a flip-chip bonding method, an anisotropic conductive film (hereinafter abbreviated as ACF) bonding method, a non-conductive film (hereinafter abbreviated as NCF) bonding method, an anisotropic conductive paste (hereinafter abbreviated as ACP) bonding method, a non-conductive paste (hereinafter abbreviated as NCP) bonding method, a wire bonding method, an ultrasonic wave bonding method, an Au—Au bonding method and a solder bonding method.

The component included in the semiconductor package of the present invention preferably includes a plurality of components that are mounted by a wire bonding method. With this configuration, a plurality of components can be mounted densely. Furthermore, it is more preferable that the component included in the semiconductor package of the present invention includes a component mounted by a wire bonding method and a component mounted by a flip-chip bonding method. With this configuration, the mounting space for components in the board can be used effectively, and therefore a semiconductor package with densely mounted components can be provided.

A component built-in module of the present invention includes: the afore-mentioned circuit board of the present invention; a component mounted with the circuit board; and an electrical insulating base for including the component therein. With this configuration, a component built-in module with densely mounted components can be provided. A board for electronic equipment of the present invention includes the afore-mentioned semiconductor package of the present invention. With this configuration, a board for electronic equipment with densely mounted components can be provided. The following describes embodiments of the present invention, with reference to the drawings.

### Embodiment 1

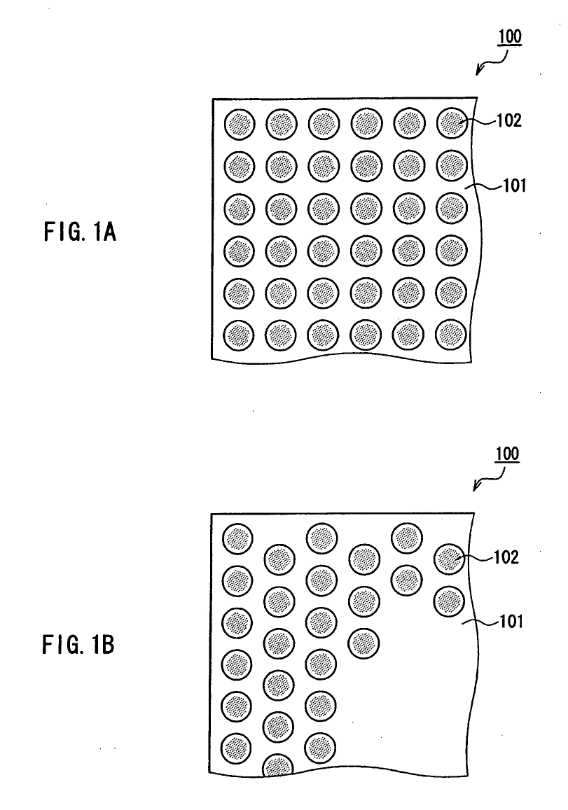

Firstly, Embodiment 1 of the present invention will be described below while referring to the drawings where appropriate. FIG. 1 referred to in the following description are plan views showing the outermost layers of a circuit board according to Embodiment 1, where FIG. 1A shows a component mounting side and FIG. 1B shows a secondary mounting side. In FIGS. 1A and 1B, reference numeral 101 denotes an electrical insulating base and 102 denotes a mounting land.

As shown in FIGS. 1A and 1B, in a circuit board 100 according to Embodiment 1, mounting lands 102 only are disposed on the surfaces of the electrical insulating base 101 on both the component mounting side and the secondary mounting side. This configuration facilitates the narrowing of a pitch of the mounting land 102 in order to support a component with a higher density and an increased number of pins. Herein, one electrical insulating base 101 may be used for constituting the circuit board 101, or a plurality of electrical insulating bases 101 may be used therefor. Although the present embodiment describes the example where, on both of the component mounting side and the secondary mounting side, no wiring for signals is provided, but the mounting lands 102 only are provided, the present embodiment is not limited to this example. For example, a circuit board can be configured so that a wiring for signals is provided on any one of the component mounting side and the secondary mounting side. Furthermore, although the present embodiment has been described so that FIG. 1A shows the component mounting side and FIG. 1B shows the secondary mounting side, FIG. 1A may be the secondary mounting side and FIG. 1B may be the component mounting side for the use.

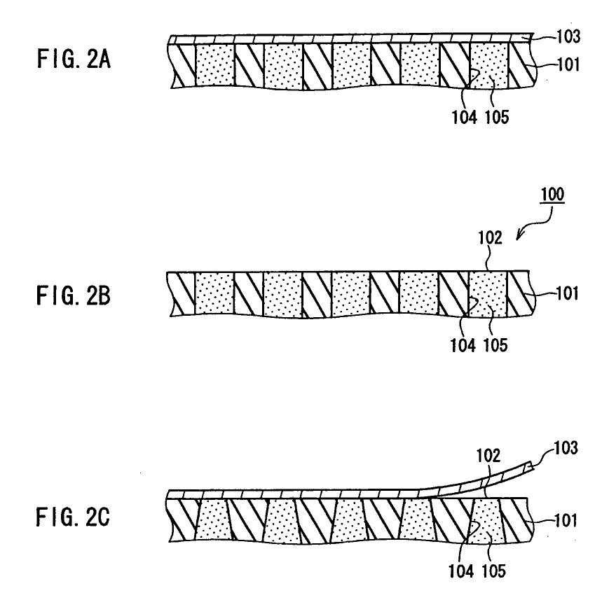

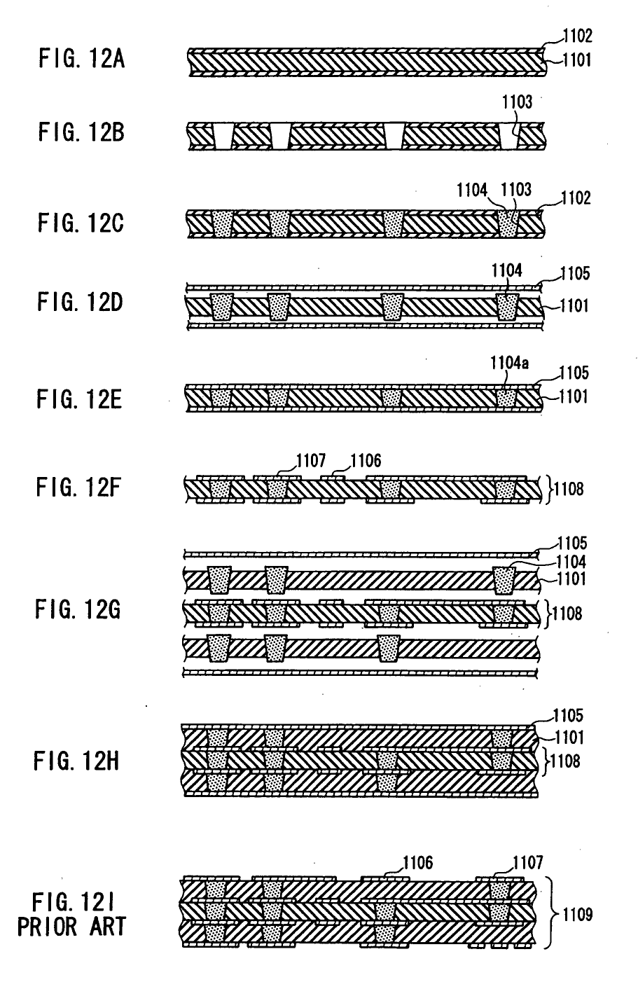

Next, a method for manufacturing the circuit board 100 according to Embodiment 1 will be described below, with reference to FIG. 2. FIGS. 2A to 2C are drawings for explaining the manufacturing method of the circuit board 100 according to Embodiment 1, showing the cross section of the electrical insulating base 101 on which the mounting lands 102 are to be formed. In FIGS. 2A to 2C, reference numeral 101 denotes an electrical insulating base, 102 denotes a mounting land, 103 denotes a metal foil, 104 denotes a via hole and 105 denotes a conductive portion. Note here that the steps until the conductive portion is formed are the same as those in the method described in the section of BACKGROUND OF THE INVENTION (See FIG. 12), and therefore their explanations omitted.

According to the manufacturing method of the circuit board 100 of Embodiment 1, a metal foil 103 (FIG. 2A) attached to the electrical insulating base 101 by hot pressing is etched all over the surface, whereby conductive portions 105 formed in the via holes 104 are exposed as shown in FIG. 2B, so that the surface of the exposed conductive portions 105 are rendered as the mounting lands 102. Thereby, the circuit board 100 can be obtained so that the mounting lands 102 are formed with the same pitch as the pitch of the via hole 104.

Herein, in the above-stated manufacturing method, the metal foil 103 is etched all over the surface so as to expose the conductive portions 105 formed in the via holes 104. Instead, the metal foil 103 may be peeled off mechanically so as to expose the conductive portions 105. In connection with this, if the via holes 104 are formed by laser, the aperture diameter of the via holes 104 would be different between the laser entrance side and the laser outgoing side of the electrical insulating base 101 as shown in FIG. 2C, so that the via holes 104 would be processed in a tapered shape. Therefore, the electrical insulating base 101 should be arranged beforehand so that the via holes 104 on the laser outgoing side, having a smaller aperture diameter, would be exposed from the surface. This can suppress the phenomenon of the conductive portions 105 being attached to the side of the metal foil 103 when the metal foil 103 is peeled off. Furthermore, the metal foil 103 may be removed mechanically by polishing so as to expose the conductive portion 105.

### Embodiment 2

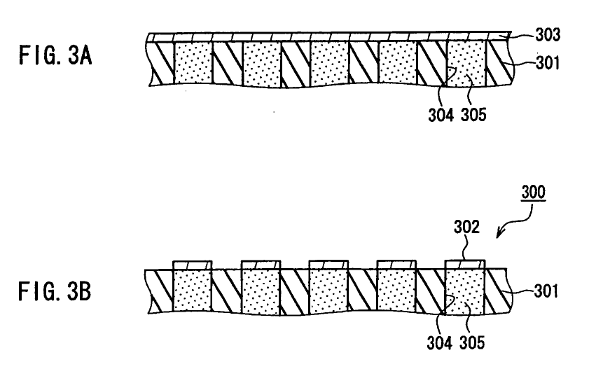

The following describes Embodiment 2 of the present invention, with reference to the drawings where appropriate. FIGS. 3A and 3B referred to in the following description are cross-sectional views showing a method for manufacturing a circuit board according to Embodiment 2, which correspond to FIGS. 2A and 2B referred to in Embodiment 1, respectively. In FIGS. 3A and 3B, reference numeral 301 denotes an electrical insulating base, 302 denotes a mounting land, 303 denotes a metal foil, 304 denotes a via hole and 305 denotes a conductive portion.

As shown in FIGS. 3A and 3B, a circuit board 300 according to Embodiment 2 is obtained as follows: the metal foil 303 (FIG. 3A) attached to the electrical insulating base 301 by hot pressing is pattern-etched using a photolithography method that is a well-known technique (FIG. 3B), whereby the mounting lands 302 having a diameter equal to or smaller than the diameter of the via holes 304 are formed. Thereby, the mounting lands 302 having the same pitch as the pitch of the via holes 304 are formed in the circuit board 300. Herein, there is no problem if the area of the mounting lands 302 is 10% or more of the area of the surface of the conductive portions 305. In the case of less than 10%, however, the connection between the conductive portion 305 and the mounting land 302 might become instable. On the other hand, when the area of the mounting lands 302 becomes closer to 100% of the area of the surface of the conductive portions 305, there is a possibility that the registration of the conductive portion 305 with the mounting land 302 is degraded. Therefore, the preferable area of the mounting lands 302 is 30 to 80% of the area of the surface of the conductive portions 305.

### Embodiment 3

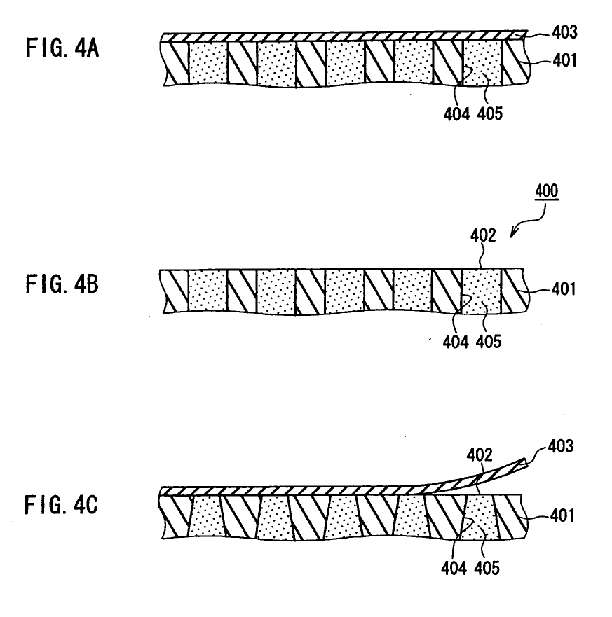

The following describes Embodiment 3 of the present invention, with reference to the drawings where appropriate. FIGS. 4A to 4C referred to in the following description are cross-sectional views showing a method for manufacturing a circuit board according to Embodiment 3, which correspond to FIGS. 2A to 2C referred to in Embodiment 1, respectively. In FIGS. 4A to 4C, reference numeral 401 denotes an electrical insulating base, 402 denotes a mounting land, 403 denotes a releasing sheet, 404 denotes a via hole and 405 denotes a conductive portion.

A circuit board 400 according to Embodiment 3 is manufactured as follows: firstly, the releasing sheet 403, instead of a metal foil, is laminated on the electrical insulating base 401 on which the mounting land 402 is to be formed (FIG. 4A). Then, after hot pressing is applied thereto, the releasing sheet 403 is peeled off so as to expose the conductive portions 405 (FIG. 4B), so as to render the surface of the conductive portions 405 as the mounting lands 402. Thereby, the mounting lands 402 having the same pitch as the pitch of the via holes 404 can be formed in the circuit board 400. According to this method, the surface of the conductive portions 405 can be exposed easily simply by peeling off the releasing sheet 403, and therefore the step for forming the mounting lands 402 can be simplified. Furthermore, if the via holes 404 are formed by laser, the aperture diameter of the via holes 404 would be different between the laser entrance side and the laser outgoing side of the electrical insulating base 401 as shown in FIG. 4C, so that the via holes 404 would be processed in a tapered shape. Therefore, the electrical insulating base 401 should be arranged beforehand so that the via holes 404 on the laser outgoing side, having a smaller aperture diameter, would be exposed from the surface. This can suppress the phenomenon of the conductive portions 405 being attached to the side of the releasing sheet 403 when the releasing sheet 403 is peeled off.

### Embodiment 4

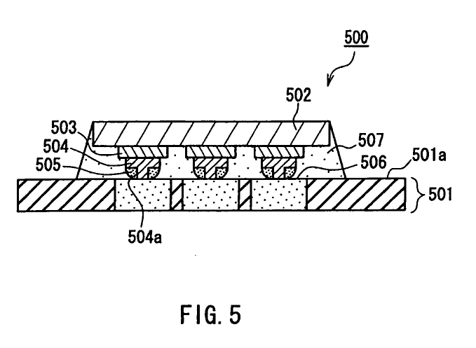

The following describes Embodiment 4 of the present invention, with reference to the drawings where appropriate. FIG. 5 referred to in the following description is a cross-sectional view showing a semiconductor package according to Embodiment 4 of the present invention. Note here that, in the semiconductor package according to Embodiment 4, a LSI is mounted on a circuit board according to any one of the above-described Embodiments 1 to 3 (single layer of the electrical insulating member is used).

As shown in FIG. 5, a semiconductor package 500 according to Embodiment 4 includes a circuit board 501 and a LSI 502. On the LSI 502, electrode pads 503 are provided, and bumps 504 further are provided on the electrode pads 503. The bumps 504 and mounting lands 506 provided on the circuit board 501 are bonded via a conductive adhesive 505 filled in step portions 504a of the bumps 504. Furthermore, a space between the LSI 502 and the circuit board 501 is filled with an epoxy based sealing resin 507. The mounting lands 506 only are provided on the surface 501a of the circuit board 501, and a wiring for signals is not provided thereon. Therefore, the semiconductor package 500 enables high-density mounting of the LSI 502.

The following describes a method for manufacturing the semiconductor package 500, with reference to FIG. 5. Firstly, Au wire is melted on electrode pads 503 provided on a LSI 502, so as to form bumps 504 having step portions 504a, thereafter a conductive adhesive 505 is transferred to the step portions 504a of the bumps 504. Then, the LSI 502 is arranged in a face-down manner and is bonded with mounting lands 506 formed on a circuit board 501, followed by the curing of the conductive adhesive 505. Next, a space between the LSI 502 and the circuit board 501 is filled with a liquid epoxy based sealing resin 507, followed by the curing of this epoxy based sealing resin 507, whereby the semiconductor package 500 can be obtained.

Note here that although a LSI is used as a component to be mounted in this embodiment, the present invention is not limited to this. For example, a resistor, a capacitor and the like may be mounted therein. In the present embodiment, although a flip-chip bonding method is adopted as the mounting method of the LSI, the present invention is not limited to this. For example, an ACF bonding method, a NCF bonding method, an ACP bonding method, a NCP bonding method, a wire bonding method, an ultrasonic wave bonding method, an Au—Au bonding method, a solder bonding method and the like may be adopted.

### Embodiment 5

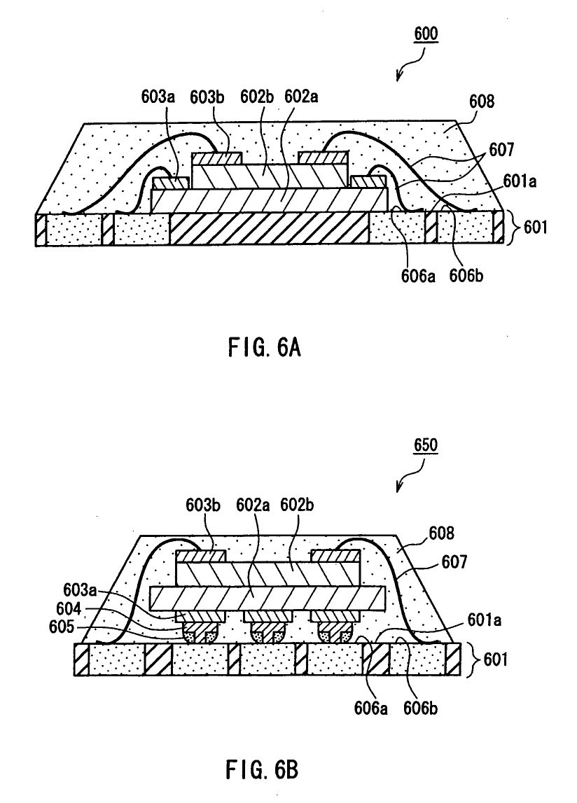

The following describes Embodiment 5 of the present invention, with reference to the drawings where appropriate. FIG. 6A referred to in the following description is a cross-sectional view showing a semiconductor package according to Embodiment 5 of the present invention. Note here that, in the semiconductor package according to Embodiment 5, a LSI is mounted on a circuit board according to any one of the above-described Embodiments 1 to 3 (single layer of the electrical insulating member is used).

As shown in FIG. 6A, the semiconductor package 600 according to Embodiment 5 includes a circuit board 601 and LSIs 602a and 602b that are provided in a face-up manner on the circuit board 601. On the LSIs 602a and 602b, electrode pads 603a and 603b are provided respectively. Then, the electrode pads 603a and 603b respectively are connected with mounting lands 606a and 606b formed on the circuit board 601 via bonding wires 607 made of Au wire. Furthermore, the LSIs 602a and 602b are molded with an epoxy based sealing resin 608. In this way, in the semiconductor package 600, the two LSIs 602a and 602b are mounted by the wire bonding method, and moreover the mounting lands 606a and 606b only are provided on the surface 601a of the circuit board 601 and a wiring for signals is not provided thereon. Therefore, the LSIs 602a and 602b can be mounted densely.

The following describes a modification example of the semiconductor package 600 according to Embodiment 5, with reference to FIG. 6B. In the following description, the same reference numerals are assigned to the same elements as in FIG. 6A, and their explanations are omitted.

As shown in FIG. 6B, a semiconductor package 650 includes: a circuit board 601; a LSI 602a that is provided on the circuit board 601 via electrode pads 603a, bumps 604 and a conductive adhesive 605 similarly to the semiconductor package 500 according to Embodiment 4 (See FIG. 5); and a LSI 602b that is provided similarly to the semiconductor package 600 (See FIG. 6A). In this way, in the semiconductor package 650, the LSI 602a is mounted by the flip-chip bonding method, and the LSI 602b is mounted by the wire bonding method, and moreover the mounting lands 606a and 606b only are provided on the surface 601a of the circuit board 601 and a wiring for signals is not provided thereon. Therefore, the LSIs 602a and 602b can be mounted densely. In the present embodiment, although a flip-chip bonding method and a wire bonding method are adopted as the mounting method of the LSIs, the present invention is not limited to this. For example, an ACF bonding method, a NCF bonding method, an ACP bonding method, a NCP bonding method, an ultrasonic wave bonding method, an Au—Au bonding method, a solder bonding method and the like may be adopted.

### Embodiment 6

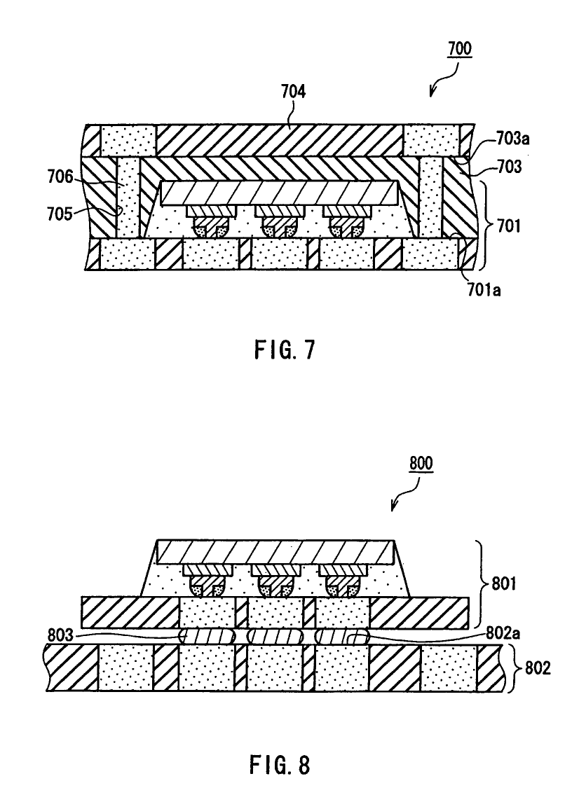

The following describes Embodiment 6 of the present invention, with reference to the drawings where appropriate. FIG. 7 referred to in the following description is a cross-sectional view showing a component built-in module according to Embodiment 6 of the present invention. Note here that the component built-in module according to Embodiment 6 includes a semiconductor package according to the above-described Embodiment 4 (See FIG. 5).

As shown in FIG. 7, a component built-in module 700 according to Embodiment 6 includes: an electrical insulating base 703; a semiconductor package 701 embedded in a cavity that is formed beforehand in this electrical insulating base 703; and a circuit board 704 laminated on the electrical insulating base 703. Interlayer connection lands 701a provided on the semiconductor package 701 and interlayer connection lands 703a provided on the surface layer of the electrical insulating base 703 are electrically connected via conductive portions 706 formed in via holes 705. In this way, the component built-in module 700 includes the semiconductor package 701 according to the above-described Embodiment 4 therein, so that the component can be mounted densely and the module can be miniaturized compared with the conventional one. As the electrical insulating base 703, a composite sheet containing inorganic fillers and a thermosetting resin such as an epoxy based resin, a phenol based resin and a cyanate based resin can be preferably used. As such a composite sheet, a composite sheet containing 70 to 95 weight % of inorganic fillers and 5 to 30 weight % of an uncured thermosetting resin composition, for example, is available.

### Embodiment 7

The following describes Embodiment 7 of the present invention, with reference to the drawings where appropriate. FIG. 8 referred to in the following description is a cross-sectional view showing a board for electronic equipment according to Embodiment 7 of the present invention. Note here that a semiconductor package according to the above-described Embodiment 4 (See FIG. 5) is secondary-mounted in the board for electronic equipment according to Embodiment 7.

As shown in FIG. 8, a board for electronic equipment 800 according to Embodiment 7 includes a motherboard 802 and a semiconductor package 801 that is secondary-mounted via cream solder 803 to lands for secondary mounting 802a provided on the motherboard 802. In this way, the board for electronic equipment 800 includes the semiconductor package 801 according to the above-described Embodiment 4, so that the component can be mounted densely and the board can be miniaturized compared with the conventional one. Note here that when manufacturing the board for electronic equipment 800, firstly, a metal mask is placed on the motherboard 802, for example, and then the cream solder 803 is printed on the lands 802a. Next, the semiconductor package 801 is mounted on the motherboard 802 via the printed cream solder 803, followed by heating of the cream solder 803 to melt the cream solder 803, so as to allow the bonding of the motherboard 802 and the semiconductor package 801 with the solder.

### Embodiment 8

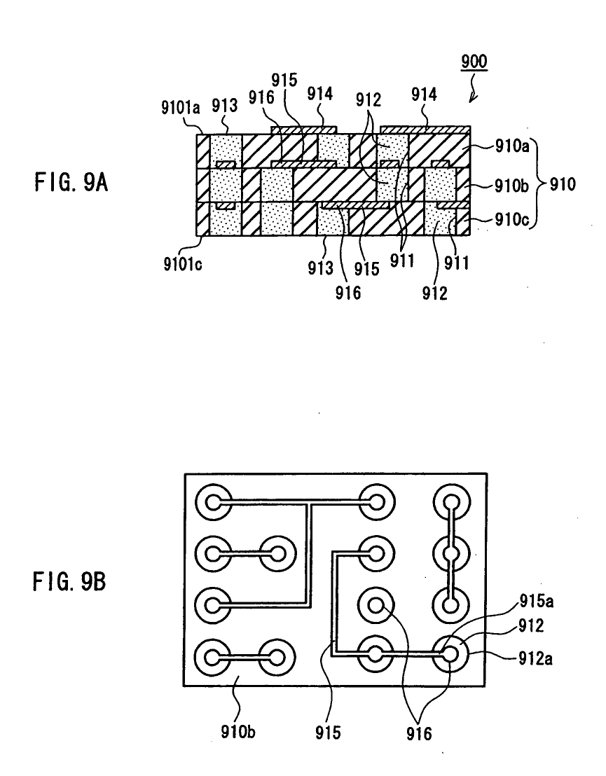

The following describes Embodiment 8 of the present invention, with reference to the drawings where appropriate. FIGS. 9A and 9B are referred to in the following description, where FIG. 9A is a cross-sectional view of a circuit board according to Embodiment 8 of the present invention, and FIG. 9B is a plan view showing internal layer wiring patterns and interlayer connection lands disposed inside the circuit board according to Embodiment 8.

As shown in FIG. 9A, a circuit board 900 according to Embodiment 8 includes: an electrical insulating layer 910 made up of three layers of electrical insulating bases 910a, 910b and 910c; and conductive portions 921 formed in via holes 911 provided in the electrical insulating bases 910a, 910b and 910c. On the surface 9101c of the electrical insulating base 910c, mounting lands 913 only, which are formed with the surface of the conductive portions 912, are disposed. Whereas, on the surface 9101a of the electrical insulating base 910a, mounting lands 913 and surface-layer wiring patterns 914 are disposed.

The circuit board 900 further includes: internal layer wiring patterns 915 disposed between the electrical insulating bases 910a and 910b and between the electrical insulating bases 910b and 910c; and interlayer connection lands 916 that are electrically connected with the conductive portions 912. As shown in the plan view showing the internal layer wiring patterns 915 and the interlayer connection lands 916, i.e., as shown in FIG. 9B that is the plan view of the internal layer wiring patterns 915 and the interlayer connection lands 916 when viewing them from the direction of axes of the conductive portion 912, the interlayer connection lands 916 are each disposed inside the outer edge 912a of the conductive portion 912. Furthermore, the internal layer wiring patterns 915 are formed with wirings thinner than the diameter of the conductive portions 912, and a portion 915a of the internal layer wiring pattern 915 that is connected with the interlayer connection land 916 is disposed so as to contact with the conductive portion 912. Thereby, in the circuit board 900, a pitch of the interlayer connection lands 916 can be narrowed, thus realizing high-density wiring easily. Furthermore, during the hot-pressing step for manufacturing the circuit board 900, since the interlayer connection lands 916 dig into the conductive portions 912 (hereinafter called a “wedge effect”), the reliability of the interlayer electrical connection can be enhanced. Note here that the outer shape of the interlayer connection lands 916 is circular in this embodiment, the present invention is not limited to this. Polygons such as triangles and quadrangles or shapes like a star are available. When the outer shape of the interlayer connection lands 916 are polygons or a star-shape, the above-stated wedge effect would be enhanced, thus further enhancing the reliability of the interlayer electrical connection.

Furthermore, in the circuit board 900, the area of the portions 915a of the internal layer wiring patterns 915 that are connected with the interlayer connection lands 916 preferably is 10% or more of the cross-sectional area of the conductive portions 912 in the radial direction. Furthermore, a sum of the area of the portions 915a of the internal layer wiring patterns 915 and the area of the interlayer connection lands 916 preferably is 10% or more and less than 100% of the cross-sectional area of the conductive portions 912 in the radial direction. When the internal layer wiring patterns 915 and the interlayer connection lands 916 are formed within the above numerical range, the densification of the wirings can be realized more easily in the circuit board 900. Note here that the circuit board 900 may be manufactured as follows: after the process similar to the manufacturing method of the circuit board 1109 as described above in BACKGROUND OF THE INVENTION (See FIG. 12), a copper foil (not illustrated) attached to the electrical insulating base 910c on the side of the surface 9101c is etched all over the surface, and a copper foil (not illustrated) attached to the electrical insulating base 910a on the side of the surface 9101a is pattern-etched so as to leave the surface-layer wiring patterns 914 only.

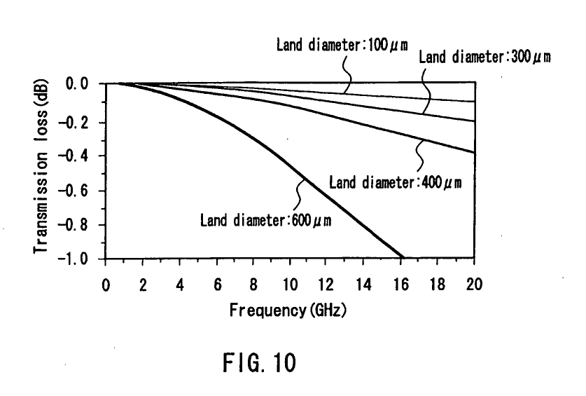

For the above-described circuit board 900, circuit boards having land diameters of the interlayer connection lands 916 of 600 μm, 400 μm, 300 μm and 100 μm were produced and their transmission losses of high-frequency signals were measured. The measurement was conducted in accordance with the resonance method described in “Proceedings of the 18^{th} Symposium of Japan Institute of Electronics Packaging” Program, 18C-02 (P1). FIG. 10 shows the results. Note here that all of the circuit boards used for the measurement had a diameter of the conductive portions 912 of 200 μm and a wiring width of the internal wiring patterns 915 of 80 μm. That is, when the land diameters of the interlayer connection lands 916 are 600 μm, 400 μm and 300 μm, such land diameters of the interlayer connection lands 916 are larger than the diameter of the conductive portions 912.

As shown in FIG. 10, it was found that the transmission loss can be suppressed in accordance with the decrease of the land diameter of the interlayer connection lands 916. Conceivably, this results from a smaller land diameter of the interlayer connection lands 916 leading to a decrease in the capacity of the capacitor between the interlayer connection lands 916 and the surface-layer wiring patterns 914, thus suppressing the transmission loss therebetween.

That is the explanation of the embodiments of the present invention. However, the present invention is not limited to the above-described embodiments. For instance, although Embodiments 1 to 3 exemplify the circuit boards for semiconductor package, needless to say, the same effects can be obtained from a circuit board for a motherboard.

### WORKING EXAMPLE

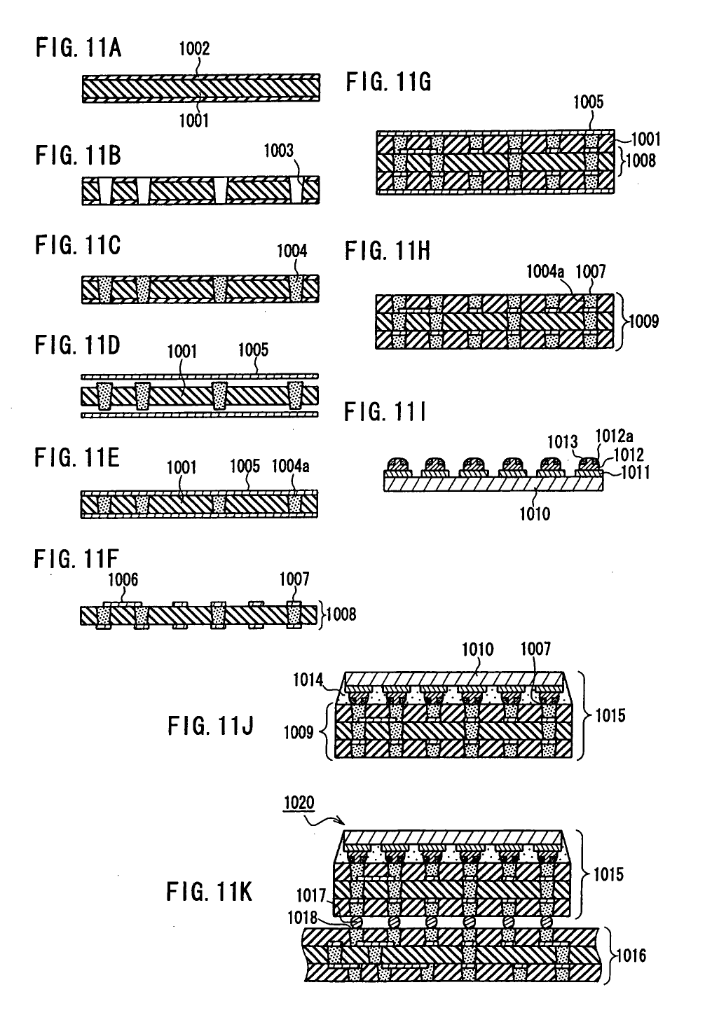

The following describes a working example of the present invention, with reference to the drawings where appropriate. FIGS. 11A to 11K referred to in the following description are cross-sectional views showing a manufacturing method of a board for electronic equipment as a working example of the present invention, which is not a limiting example.

Firstly, as shown in FIG. 11A, an electrical insulating base 1001 of 100 μm in thickness was prepared by impregnating a non-woven cloth (weight: 72 g/cm²) made of aramid fiber (12 μm in diameter and 3 mm in length) with an epoxy resin, and polyethylene terephthalate (PET) films 1002 of 19 μm in thickness were attached to both the surface and the rear face of the electrical insulating base 1001 by laminating (130° C., 2 MPa). In this step, if the adhesive strength of the electrical insulating base 1001 and the PET films 1002 is too small, they would be delaminated during the via hole formation process, which will be described later. On the other hand, too large strength would cause a failure to peel off the PET films 1002, and therefore care should be given to this point.

Next, as shown in FIG. 11B, via holes 1003 (diameter: about 200 μm) were formed by CO₂ gas laser at predetermined positions of the electrical insulating base 1001 with the PET films 1002 attached thereon. Furthermore, as shown in FIG. 11C, the via holes 1003 were filled with a conductive paste 1004. When filling with the conductive paste 1004, the electrical insulating base 1001 was placed on a table of a printing apparatus, and the conductive paste 1004 was directly applied from above the PET film 1002 for the printing. In this step, the PET films 1002 functioned so as to prevent the conductive paste 1004 from remaining on the principle surface of the electrical insulating base 1001 and to secure the amount of the conductive paste 1004 corresponding to the thickness of the PET film 1002. Herein, as the material constituting the conductive paste 1004, spherical copper powder coated with silver (average particle size: 2 μm) was used as the conductive fillers; an epoxy resin, which was the thermosetting resin used for the electrical insulating base 1001, was used for the resin constituting the paste; and an amine based hardener was used as the hardener. The contents of these materials were 85 weight % of the conductive filler, 12.5 weight % of the constituting resin and 2.5 weight % of the hardener.

Then, the PET films 1002 on both sides were peeled off, and as shown in FIG. 11D, metal foils 1005 were disposed on both the surface and the rear face of the electrical insulating base 1001. As the metal foil 1005, copper foil of 12 μm in thickness with both surfaces treated to be rough was used. Following this, as shown in FIG. 11E, the electrical insulating base 1001 and the metal foils 1005 were thermally compressed by hot-pressing (200° C., 5 MPa, 1 hour in a vacuum). During this thermal compression, the conductive pastes 1004 were compressed in the thickness direction of the electrical insulating base 1001, whereby metal fillers included in the conductive paste 1004 contact with each other densely, so as to form conductive portions 1004a and to establish the electrical connection between the metal foils 1005 and the conductive portions 1004a.

Next, as shown in FIG. 11F, a circuit pattern was formed by a photolithography method. Firstly, a dry film resist of 7 μm in thickness (NIT-215 produced by Nichigo-Morton Co., Ltd., not illustrated) was attached on the metal foil 1005 by laminating. Following this, a film mask (not illustrated) on which a desired circuit pattern has been depicted was placed on the dry film resist, followed by exposure, and development, etching and peeling procedures, so that the desired circuit pattern was formed to obtain a double-sided circuit board 1008. The circuit pattern includes wirings for signals 1006, lands 1007 and the like. Herein, the lands 1007 were formed to have a diameter smaller than the diameter of the conductive portions 1004a, and the wirings for signals 1006 that would be connected with the conductive portions 1004a were formed to have a width smaller than the diameter of the conductive portions 1004a. Herein, in this working example, the conductive portions 1004a and the lands 1007 were formed to have diameters of 200 μm and 130 μm, respectively, and the wirings for signals 1006 were formed to have a width of 100 μm.

Then, as shown in FIG. 11G, on each of the surface and the rear face of the double-sided circuit board 1008, the electrical insulating base 1001 filled with the conductive paste 1004 by the procedure shown in FIGS. 11A to 11D and the metal foil 1005 were disposed, which were then thermally compressed by hot-pressing (200° C., 5 MPa, 1 hour in a vacuum). Herein, as the metal foil 1005, copper foil of 18 μm in thickness with one surface treated to be rough was used, which was arranged so that its glossy surface faced the inside.

Then, as shown in FIG. 11H, the metal foils 1005 were each etched all over the surface so as to expose the conductive portions 1004a, thus rendering the surface of the conductive portions 1004a as lands 1007 to obtain a circuit board 1009. Thereby, the lands 1007 could be formed to have the same pitch (150 μm) as the pitch of the conductive portions 1004a, i.e., the pitch of the via holes 1003. Then, the surface of the lands 1007 was polished, thereafter an electroless Ni—Au plating was applied thereto (Ni thickness: 5 μm, Au thickness: 0.05 μm). When polishing the surface of the lands 1007, a planar polishing method using a grinder was adopted, so as to suppress the deformation of the polished surface to allow for the flat surface polishing.

Then, as shown in FIG. 11I, on electrode pads 1011 provided on a LSI 1010, which was separately prepared, bumps 1012 were formed to have step portions 1012a by melting Au wire, and an epoxy based conductive adhesive 1013 was transferred on the step portions 1012a of the bumps 1012. Herein, the shape of each bump was as follows: the diameter of the base was 60 μm, the overall height was 40 μm, the height of the protrusion was 18 μm and the diameter of the protrusion was 25 μm.

Then, as shown in FIG. 11J, the LSI 1010 was arranged in a face-down manner, and the LSI 1010 was mounted on the circuit board 1009, followed by the curing of the conductive adhesive 1013, and thereafter a space between the LSI 1010 and the circuit board 1009 was filled with an epoxy based sealing resin 1014. In this way, the use of the circuit board 1009 having the narrow-pitch lands 1007 at the outermost surface-layer allowed a semiconductor package 1015 to be obtained, in which a component (LSI 1010) was mounted densely. Incidentally, in general, LSIs having a pin pitch of 0.8 mm are used mainly for a semiconductor package. On the other hand, in this working example, a CSP (Chip Size Package) having a pin pitch of 0.30 mm was used as the LSI 1010 to manufacture the semiconductor package 1015.

Next, as shown in FIG. 11K, the semiconductor package 1015 was secondary-mounted on a motherboard 1016, so as to manufacture a board for electronic equipment 1020. The secondary mounting was conducted by soldering, more specifically, a metal mask (not illustrated) was overlaid on the motherboard 1016, wherein apertures were provided in the metal mask at positions corresponding to lands for secondary-mounting 1018 formed on the motherboard 1016. Then, cream solder 1017 prepared by dissolving solder particles in a solvent was supplied at one end on the metal mask, and the apertures were filled with the cream solder 1017 by screen-printing. Next, the metal mask was removed from the motherboard 1016 so as not to deform the cream solder 1017, and the semiconductor package 1015 was placed on the cream solder 1017. Then, the printed cream solder 1017 was melted by reflow process so as to vaporize the solvent included in the cream solder 1017, followed by the curing of the cream solder 1017, thus fixing the semiconductor package 1015 onto the motherboard 1016.

In order to evaluate the reliability of the interlayer electrical connection of the thus manufactured board for electronic equipment 1020, a temperature cycling test was conducted thereto. The temperature cycling test was carried out so that after the board for electronic equipment 1020 was allowed to stand at −65° C. for 30 minutes, it was then allowed to stand at 150° C. for 30 minutes, which was set as one cycle, and 1000 cycles were repeated. As a result, no significant changes of resistance values of the electrical connections at both the composition mounting and connecting portions and the secondary mounting and connecting portions of the board for electronic equipment 1020 were found after the temperature cycling test.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1-4. (canceled)

5. A circuit board, comprising:
an electrical insulating layer comprising at least two layers of electrical insulating base, and a conductive portion formed in a via hole provided in the electrical insulating base,
wherein the circuit board has a land for mounting disposed on at least one surface of the electrical insulating base arranged at an outermost layers,
an interlayer connection land that is electrically connected with the conductive portion, and
a wiring pattern disposed between the electrical insulating bases and connected with the interlayer connection land; and
wherein when viewing the interlayer connection land from a direction of an axis of the conductive portion, the interlayer connection land is disposed inside an outer edge of the conductive portion.

6. The circuit board according to claim 5, wherein the wiring pattern is formed with a wiring thinner than a diameter of the conductive portion, and a part of the wiring pattern that is connected with the interlayer connection land is disposed so as to contact with the conductive portion.

7. The circuit board according to claim 6, wherein when viewing the wiring pattern from the direction of the axis of the conductive portion, a portion of the wiring pattern that is disposed on the conductive portion has an area that is 10% or more of a cross-sectional area of the conductive portion in a radial direction.

8. The circuit board according to claim 6, wherein when viewing the wiring pattern and the interlayer connection land from the direction of the axis of the conductive portion, a total area of a portion of the wiring pattern that is disposed on the conductive portion and an area of the interlayer connection land is 10% or more and less than 100% of a cross-sectional area of the conductive portion in a radial direction.

9-21. (canceled)
